(19) United States
(12) Patent Application Publication
(10) Pub. No.: US 2004/0127045 A1
(43) Pub. Date: Jul. 1, 2004

(54) Chemical mechanical planarization of wafers or films using fixed polishing pads and a nanoparticle composition

(76) Inventors: Venkata R. K. Gorantla, Potsdam, NY (US); Suryadevara V. Babu, Potsdam, NY (US)

Correspondence Address: Thomas H. Close, Patent Legal Staff, Eastman Kodak Company, 343 State Street, Rochester, NY, 14650-2201, US

(21) Appl. No.: 10/662,215

(22) Filed: Sep. 12, 2003

Related U.S. Application Data
(60) Provisional application No. 60/409,992, filed on Sep. 12, 2002.

(51) Int. Cl. H01L 21/302; H01L 21/461

(52) U.S. Cl. 438/690

(57) ABSTRACT

An aqueous composition for chemical mechanical planarization of a wafer or film using a fixed polishing pad, includes:

(a) from about 0.2 to about 10 weight % of abrasive nanoparticles having an average particle size of between about 10 and about 200 nanometers; and

(b) from about 90 to about 99.8 weight % of water;

wherein the pH of the composition is between about 3 and about 5 or between about 9 and about 12, and the composition does not comprise polyelectrolytes. Also included is a one step process for chemical mechanical planarization of topographical structures of oxide filled wafers or films using a fixed polishing pad and an abrasive composition.

### CROSS REFERENCE TO RELATED DOCUMENT

Benefit is claimed under 35 USC 119(e) of provisional U.S. patent application No. 60/409,992, filed on Sep. 12, 2002.

### FIELD OF THE INVENTION

The invention relates to a process for chemical mechanical planarization in the microelectronics industry; more particularly, chemical mechanical planarization of fixed pattern wafers, or shallow trench isolation films or the like using a fixed polishing pad and a less than or equal to about 10 weight % aqueous composition of abrasive nanoparticles.

### BACKGROUND OF THE INVENTION

Removal of dielectric films, silicon dioxide, and silicon nitride by Chemical Mechanical Polishing (CMP) has been moderated heretofore by the interaction of abrasive particulate within a slurry. Such slurry solutions were found to have a strong effect on the polishing chemistry and relative removal rates of dielectric films.

Chemical Mechanical Planarization relies on mechanical means with chemical activity to remove and ultimately planarize the top film or films on wafers or the like during semiconductor processing. The mechanical action during chemical mechanical planarization, including table speed, applied force, pad hardness, etc., are typically used to control rate, planarity, and uniformity. The chemical reactions that occur during chemical mechanical planarization help to achieve selectivity and combat erosion, dishing, etc.

With the continuing reductions in size of silicon integrated circuit (IC) devices, and an associated increase in device packing density on a chip, greater expectations are being placed on chemical mechanical planarization (CMP) to achieve better results than ever before.

Shallow trench isolation (STI) is an isolation method of choice. STI isolates the various devices in a layer during the manufacture of integrated circuits. It has the advantage of providing higher packing density for such devices. In the Shallow Trench Isolation process, silicon dioxide is used as the isolating material. A layer of silicon nitride is deposited on silicon and a shallow trench is etched into the substrate, often using photolithography masks. Silicon dioxide is then deposited into the trench and over the nitride layer. The excess oxide on the top of nitride must be removed and the trench planarized in order to prepare for the next step, which is usually the growth of gate oxide and deposition of poly silicon gate.

Chemical mechanical planarization is used for removing the excess oxide and planarizing the substrate and the trench. The silicon nitride acts as a stop layer, preventing the polishing of underlying silicon substrate. In order to achieve adequate planarization with minimal overpolishing, a slurry with a high oxide to nitride removal rate ratio has been used in the past for chemical mechanical planarization. Such slurries have included an aqueous medium with abrasive particles, a compound with a carboxylic acid group and an electrophilic functional group. In the past, the slurry was applied at a polishing interface between a polishing pad and the composite comprised of silicon dioxide and silicon nitride.

It has been observed that the chemical mechanical planarization process using fixed abrasive pads is very sensitive to the topography on the wafer or film, resulting in slow removal rates once planarity is attained on the wafer. It has been found that this fixed abrasive chemical mechanical planarization process results in slow material removal rates of high pattern density structures of the wafer, if the percentage of low pattern density structures on the wafer surface is insufficient. This can result in high polish times and uneven material removal across the wafer.

On the other hand, in a conventional chemical mechanical planarization process, when the nano-size abrasives of the present invention are used on conventional porous polishing pad, they become entrapped in the pores and trenches of these pads without effectively contacting the wafer surface being polished, thus resulting in slow removal rates.

In the present invention, a composition containing nano-size abrasives are used on a fixed abrasive pad. These nanoparticles are effectively brought into contact with the wafer surface by the flat cylindrical (or any other shape) structures on the fixed abrasive pad, thus resulting in dramatic enhancement of the material removal rates of blanket films, as well as those of patterned wafers. The structures on the fixed abrasive pad may be of different geometric shapes, such as cylindrical, pyramidal, hexagonal, square, rectangular etc. The structures on fixed abrasive pads generally contain abrasives embedded in them. The composition and process of the present invention allow chemical mechanical planarization to proceed, regardless of whether abrasives have been bound into the structures of the polishing pad.

### SUMMARY OF THE INVENTION

A one-step process and composition for optimizing and speeding chemical mechanical planarization has been found. Chemical and mechanical effects of the present nanoparticle composition itself enhance the chemical mechanical planarization process and increase removal rates. Also, the composition of the present invention is believed to release additional bound abrasive from the fixed abrasive pad. It has been found that the compositions and process of the present invention allow quick, efficient chemical mechanical planarization, even when polishing pads without abrasives bound in them are utilized.

The present invention is an aqueous composition for chemical mechanical planarization of a fixed pattern wafer or film using a fixed polishing pad, which includes:

(a) from about 0.2 to about 10 weight % of abrasive nanoparticles having an average particle size of between about 10 and about 200 nanometers; and

(b) from about 90 to about 99.8 weight % of water;

wherein the pH of the composition is between about 3 and about 5 or between about 9 and about 12, and the composition does not comprise polyelectrolytes.

The present invention also includes a one-step process for chemical mechanical planarization of a wafer, regardless of wafer topography, using a fixed polishing pad, comprising the steps of:

a) mechanically polishing the wafer with the pad; and

b) feeding an aqueous composition comprised of abrasive nanoparticles to the pad during planarization, the composition having a pH of between about 3 and about 5 or between about 9 and about 12.

### BRIEF DESCRIPTION OF THE DRAWINGS

A more complete understanding of the invention and its advantages will be apparent from the detailed description taken in conjunction with the accompanying drawings, wherein examples of the invention are shown, and wherein:

FIG. 1 is a schematic view of a shallow trench isolation structure according to the present invention, shown prior to chemical mechanical planarization;

FIG. 2 is a schematic view of a blanket wafer being polished with a fixed abrasive pad and a nanoparticle composition according to the present invention; and

FIG. 3 is a schematic view of a fixed pattern wafer being polished with a fixed abrasive pad according to the process of the present invention.

### DETAILED DESCRIPTION OF THE INVENTION

In the following description, like reference characters designate like or corresponding parts throughout the several views. Also, in the following description, it is to be understood that such terms as “top,” “above,” “below,” and the like are words of convenience and are not to be construed as limiting terms. Referring in more detail to the drawings, the invention will now be described.

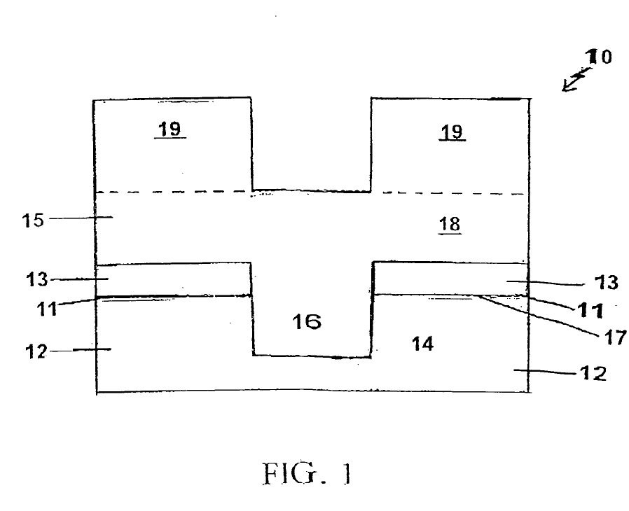

Turning first to FIG. 1, an oxide-filled Shallow Trench Isolation (STI) structure 10, which is preferably a semiconductor wafer, is shown prior to the initiation of chemical mechanical planarization. In the Shallow Trench Isolation process, a thin silicon dioxide (pad-oxide) layer 11 is first grown on a silicon wafer base 12, followed by the deposition of a silicon nitride layer 13. The oxide layer 11 relieves the stresses that could develop between the nitride layer 13 and the silicon wafer base 12. Shallow trenches 14 are etched into the wafer base 12. These trenches cut through the nitride film and the thin oxide layer. They are filled with silicon dioxide 15, which provides electrical isolation of active devices that will be fabricated in the regions between the trenches. Since silicon dioxide placement is not precise, it is also deposited on top of the nitride film during the filling of these shallow trenches 14.

Continuing with FIG. 1, the areas within the trenches 14 are referred to as the “Down” areas 16 and the areas having the nitride on the silicon are called “Up” areas 17 herein. The oxide between the “Down” areas 16 and the nitride film 13 is referred to as oxide overfill 18. The two matching areas above the oxide overfill 18, the top of which is indicated by a dashed line in FIG. 1, are referred to herein as steps 19. The vertical walls shown in FIG. 1 are an idealization. Chemical mechanical planarization has been used to flatten the step heights 19 and “Up” areas 17 and then thin out the “Down” areas 16, so as to achieve a planar surface. Heretofore, two solutions have been utilized, a first aqueous polyelectrolyte or amino acid solution to flatten the “Up” areas, followed by an aqueous solution with conventional size abrasive particles to thin out the “Down” areas. Thus, a separate Chemical Mechanical Planarization step is performed to planarize the surface topography. In some cases, a thick fill of oxide, or a wafer with large filled trench areas, requires a lengthy time period to planarize the surface topography. With the present invention, this is a one step rather than a two step process, which saves time and unnecessary complication. The composition of the present invention, which preferably does not include polyelectrolytes or amino acids, can be used instead of two aqueous solutions being required. Two separate input lines and fill tanks are therefore not required.

Fixed abrasive polishing is well suited for the special needs of Shallow Trench Isolation chemical mechanical planarization. During fixed abrasive Shallow Trench Isolation chemical mechanical planarization, the polish rate drops significantly once planarity is achieved.

Although conventional, commonly available ceria or silica particles, which are many times larger than the nanoparticles (e.g., about 200 to 500 nanometers versus 20 nanometers for a nanoparticle), are known to be efficient abrasives, it has been found that nanoparticle compositions are not efficient polishers when coupled with porous polishing pads. Such pads are often made of polyurethane. It is believed that this is because these extremely small particles become trapped in the grooves and pores of the porous pad structure. However, it has been found that the nanosized particles of the present invention when used in aqueous solution with a fixed polishing pad during chemical mechanical planarization, with or without bound abrasives in the pad, have a surprisingly beneficial effect on planarization. Without meaning to be bound by theory, it is believed that, for a given concentration, the nanoparticles provide increased surface area for contact with the oxide layer on the wafer or film. Fixed abrasive pads are substantially nonporous.

It is believed that the effect of the nanoparticle composition is two-fold. First, there is a chemical reaction between the oxide and the abrasive nanoparticles, which enhances chemical mechanical planarization. Secondly, with fixed abrasive pads, the nanoparticles help to break down the polymer or other structures of the pad, increasing the release rate of the bound abrasives from the pad. The formerly bound abrasives then assist in planarization.

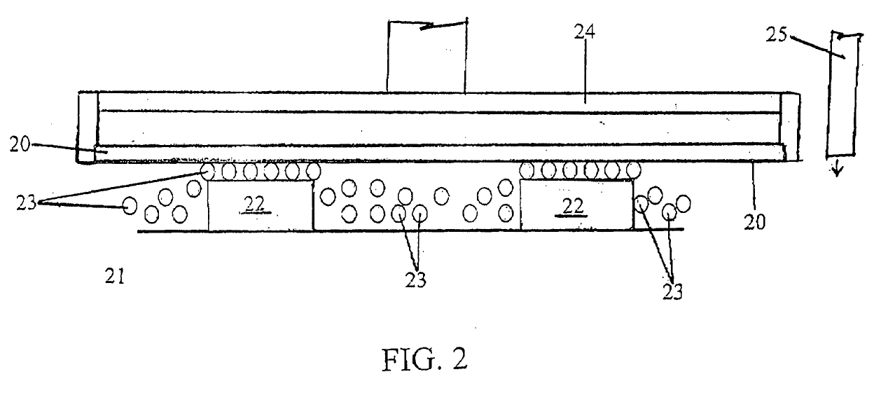

Turning to FIG. 2, chemical mechanical planarization is ordinarily conducted by placing a semiconductor wafer, such as a blanket wafer 20 upside down on a fixed polishing pad 21. The fixed polishing pad 21, which is substantially nonporous, has pad structures 22 that project out from its surface, which facilitate polishing of the blanket wafer 20. The nanoparticles 23 in the aqueous composition are spread across the surfaces of the pad and wafer by the circular or linear motion of the polishing pad 21, which is fixed on a rotatable platen. Since they are small, the nanoparticles 23 also migrate into small spaces, such as the spaces between the pad structures 22, and between the pad structures 22 and the blanket wafer 20, where they have both chemical and mechanical action. The blanket wafer 20 is held by a carrier 24. Pad structures may be cylindrical, pyramidal, hexagonal, square, rectangular, etc. in shape.

Continuing with FIG. 2, the nanoparticle composition is preferably continuously metered from a storage vessel (not shown) through a supply line or tubing 25 in the area of the fixed abrasive pad 21 using a pump and flow controller. The nanoparticle composition is slowly discharged from an end of the tubing 25 during chemical mechanical planarization. Alternatively, a spray rod with multiple holes may be used to disperse the nanoparticle composition in the pad area.

During polishing, the carrier 24 and platen are rotated in the same direction (usually counterclockwise) at the same speed, preferably about 40 to 60 rotations per minute. Pad rotation is also set, preferably about 40 to 60 rotations per minute.

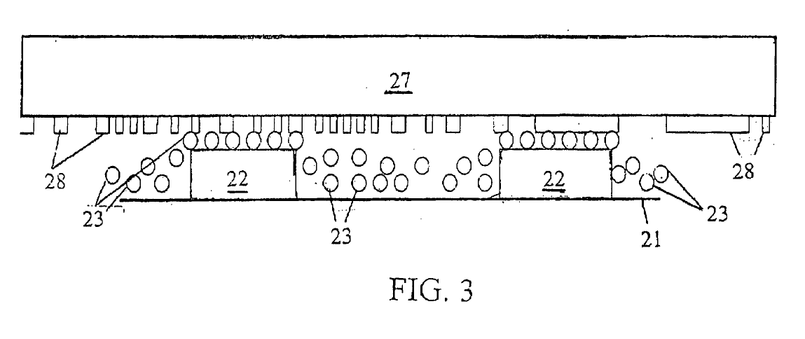

Referring to FIG. 3, a fixed patterned wafer 27 and its topographical structures 28 is mounted face down against the pad structures 22 of a fixed abrasive pad 21. Nanoparticles 23 are shown in the spaces between pad structures 23 and between the pad structures 23 and the topographical structures 28 on the patterned wafer 27. No polyelectrolyte solution or additional step is needed to plane the topographical structures of the wafer.

The aqueous compositions herein include:

(a) from about 0.2 to about 10 weight % of abrasive nanoparticles having an average particle size of between about 10 and about 200, more preferably between about 10 and about 100, most preferably between about 15 and about 50, nanometers; and

(b) from about 90 to about 99.8 weight % of water;

wherein the pH of the composition is between about 3 and about 5 or between about 9 and about 12. The composition does not comprise polyelectrolytes, and preferably does not include amino acids, which have traditionally been employed for planing wafer topography. In fact, it is more preferred that the nanoparticle compositions herein not include additional ingredients other than the nanoparticles and a pH agent.

The size of the abrasive particles herein is considered to be important. The number of particles with a diameter greater than about 100 nanometers in the composition is preferably less than about 1 weight %. It has been found that the larger abrasive particles disrupt the action of the nanoparticles; substantially pure nanoparticle compositions are preferred herein.

As desired, the nanoparticle compositions herein facilitate the removal of the oxide layer from the step heights 19, but not from the trenches 14 (see FIG. 1). The nitride layer of the wafer or film is left intact. In addition to efficient removal, the rates of removal are increased, regardless of whether the step heights 19 are being removed or the lower-down oxide overfill area 18 (see FIG. 1).

The nanoparticles are preferably metal oxides, such as ceria (most preferred), silica (preferred), alumina, titania, zirconia, and germania. Ceria and fumed silica are preferred. In one example, the abrasive particles are cerium oxide and a weight percentage of the abrasive particles in the aqueous solution is 0.5 weight %. The amount of ceria nanoparticles in the compositions herein is preferably from about 0.2 to about 3, most preferably 0.4 to 1, weight %. A higher amount of silica is preferred for use herein. The amount of silica nanoparticles in the compositions herein is preferably from about 1 to about 5, most preferably 3 to 4, weight %. Individual nanoparticles may be spherical, cubic, ellipsoidal, etc. in shape. Nanoparticles for use herein may also be hematite, magnesia, yttria, tin oxide, or a polymer. They may be made from colloidal dispersions or using conventional fumed pyrolysis technology.

Although ceria has been found to optimize efficiency of the chemical mechanical planarization process, ceria is relatively costly. It has been found that a combination of ceria and silica, which is relatively inexpensive, in a ratio of between about 10:1 and about 1:10 ceria: silica both works well and optimizes cost.

In another composition according to the present invention, a substantial majority of the nanoparticles are silica nanoparticles coated with a number of smaller ceria nanoparticles, the average particle size of the ceria nanoparticles being less than about half the average particle size of the silica nanoparticles. In an alternate composition according to the present invention, the nanoparticles are silica nanoparticles having an average particle size of between about 10 and about 50 nanometers, a substantial number of the silica nanoparticles being substantially coated with ceria nanoparticles, the ceria nanoparticles having an average particle size between about 1 and about 5 nanometers.

The CMP substrate herein is preferably a fixed pattern wafer or blanket film. The fixed polishing pad used herein is preferably a fixed abrasive pad. The composition and process herein may be used wherever fixed abrasive pads are used for polishing. The composition and process herein may also be used for metal films, made from copper or tantalum, for example.

The aqueous compositions herein preferably have a pH between about 3 and about 5, or between about 9 and about 12, more preferably between about 9 and about 11. The compositions herein have been found to be more effective during chemical mechanical planarization when they are at a pH within these acidic or alkaline ranges, perhaps because this pH favors chemical reaction between the abrasive nanoparticles and the oxide layer, or between the nanoparticles and the pad structure. It is believed that ceria nanoparticles tend to agglomerate at neutral pH, decreasing their effectiveness.

Agents suitable for lowering the pH of the aqueous compositions herein include sulfuric acid, perchloric acid, hydrochoric acid, phosphoric acid, and nitric acid. pH agents suitable for raising the pH of the aqueous compositions herein include potassium hydroxide, sodium hydroxide, and ammonium hydroxide. For example, a composition herein may include perchloric acid, hydrochloric acid, or nitric acid in an amount sufficient to maintain the pH of the composition at between about 3 and about 5, or sodium or potassium hydroxide in an amount sufficient to maintain the pH of the composition at between about 9 and about 12.

The compositions herein preferably further comprise from about 0.3 to about 3 weight % of a substantially water-soluble surfactant. The surfactant is believed to minimize formation of hard agglomerates of nanoparticles in the nanoparticle composition, and may reduce friction force between the pad and the wafer. Surfactants for use herein are substantially water-soluble nonionic (preferred), anionic (preferred), cationic, amphoteric, or zwitterionic surfactants. Suitable nonionic surfactants for use herein are polyethyleneglycol (PEG), and polyhydroxy alcohol. Suitable anionic surfactants for use herein are carboxylic acids and salts thereof, phosphoric esters and salts thereof, sulfuric esters and salts thereof, or sulfonic acids and salts thereof. Cationic surfactants for use herein include primary secondary, tertiary, or quaternary amines and salts thereof.

Also included herein is a one-step process for chemical mechanical planarization of a wafer, regardless of wafer topography, using a fixed polishing pad, preferably a fixed abrasive pad. The process comprises the steps of:

a) mechanically polishing the wafer with the pad; and

b) feeding an aqueous composition comprised of abrasive nanoparticles to the pad during planarization, the composition having a pH of between about 3 and about 5 or between about 9 and about 12. No extra pre-step of adding a polyelectrolyte solution to diminish topographic features is needed. It is not necessary to add any slurries other than the nanoparticle wash to the pad during polishing. The process most preferably consists essentially of steps a) and b).

The following examples are intended to further illustrate the invention and facilitate its understanding. These examples are given solely for the purposes of illustration and are not to be construed as limiting the present invention in any way.

### EXAMPLE I

Four slurries were formed by dispersing silica abrasives of average particle aggregate diameter 200 nanometers (nm) or ceria particles of average particle diameter 20 nm, in a certain weight percentage as shown in Table I, in deionized water. The pH of the slurry was adjusted to 10 by addition of a sufficient amount of 40% by weight solution of potassium hydroxide.

Blanket silicon wafers (6 inch diameter) having 3.5 micron silicon dioxide film layer applied by tetraethylorthosilicate (TEOS) precursor chemical vapor deposition were polished using a Westech 372 polisher and a Rodel IC 1400 K grooved pad. The polishing conditions were: 3 psi down pressure; 0 psi back pressure; 40 rpm table speed; 40 rpm quill speed; 25 degrees C. temperature, and 300 cc/mm slurry flow rate. The amount of silicon dioxide removed from the surface of the silicon wafer by CMP was measured using an optical interferometer to determine the rate of removal in terms of Angstroms of silicon dioxide per minute.

TABLE I

| | Abrasive | Silicon dioxide |
|---|---|---|
| | Concentration | removal rate |
| Type of abrasive | (wt %) | (A/min) |
| Silica | 0.5% | ˜0 |
| Silica | 3.0% | 200 |
| Ceria | 0.5% | ˜0 |
| Ceria | 3.0% | 40 |

In summary, Example I demonstrates that the blanket oxide removal rates with the nanosized particles on a groove porous polishing pad are very low.

### EXAMPLE II

Two slurries were formed by dispersing 3 weight % concentration silica abrasives of average particle aggregate diameter 200 nm or 3 weight % concentration ceria particles of average particle diameter 20 nm in deionized water. The pH of the slurry was adjusted to 10 by addition of a sufficient amount of 40% by weight solution of potassium hydroxide.

Patterned silicon wafers (6″ diameter) of an uniform pattern density of 50%, having a silicon dioxide film layer applied by tetraethylorthosilicate (TEOS) precursor chemical vapor deposition and the step height of the silicon dioxide ˜7300 Angstroms, were polished using a Westech 372 polisher and a Rodel IC 1400 K grooved pad. Layers of different materials like silicon nitride may be present underneath the silicon dioxide film and above the silicon wafer in the ‘UP’ areas (active areas) in FIG. 1. The polishing conditions were: 3 psi down pressure; 0 psi back pressure; 40 rpm table speed; 40 rpm quill speed; 25 degrees C. temperature, and 300 cc/mm slurry flow rate. The reduction in the step height of the silicon dioxide from the surface of the silicon wafer by CMP was measured using a stylus profilometer to determine the rate of step height reduction in terms of Angstroms of silicon dioxide per minute. The polishing rates are reported in Table II below.

TABLE II

| | Abrasive | Silicon dioxide |
|---|---|---|
| | Concentration | Step hght reductn rate |
| Type of abrasive | (wt %) | (A/min) |
| Silica | 3.0% | 350 |
| Ceria | 3.0% | 100 |

In summary, Example II demonstrates that the step height reduction rates of the uniformly patterned 50% pattern density structures with the nanosized particles on a groove porous polishing pad are very low.

### EXAMPLE III

The slurry was formed by using deionized water only, and the pH of the slurry was adjusted to 10 by addition of a sufficient amount of 40% by weight solution of potassium hydroxide.

Blanket silicon wafers (6″ diameter) having 3.5 micron silicon dioxide film layer applied by tetraethylorthosilicate (TEOS) precursor chemical vapor deposition were polished using a Westech 372 polisher and a 3M fixed abrasive pad SWR159 with cylindrical structures on it. The polishing conditions were: 3 psi down pressure; 0 psi back pressure; 40 rpm table speed; 40 rpm quill speed; 25 degrees Centigrade temperature, and 300 cc/mm slurry flow rate. The amount of silicon dioxide removed from the surface of the silicon wafer by CMP was measured using an optical interferometer to determine the rate of removal in terms of Angstroms of silicon dioxide per minute. The polish rate was 100 A/minute for silicon dioxide.

In summary, Example III demonstrates that the blanket silicon dioxide removal rates with just pH adjusted DI water on a fixed abrasive polishing pad are very low.

### EXAMPLE IV

The slurry was formed by using deionized water only and the pH of the slurry was adjusted to 10 by addition of a sufficient amount of 40% by weight solution of potassium hydroxide.

Patterned silicon wafers (6 inch diameter) of an uniform pattern density of 50%, having a silicon dioxide film layer applied by tetraethylorthosilicate (TEOS) precursor chemical vapor deposition and the step height of the silicon dioxide ˜7300 Angstroms, were polished using a Westech 372 polisher and a fixed abrasive pad SWR159 with cylindrical structures on it, or a fixed abrasive pad SWR1 92 with pyramidal structures on it (shown in Table III). Layers of different materials like silicon nitride may be present underneath the silicon dioxide film and above the silicon wafer in the ‘UP’ areas (active areas) in FIG. 1. The polishing conditions were: 3 psi down pressure; 0 psi back pressure; 40 rpm table speed; 40 rpm quill speed; 25 degrees C. temperature, and 300 cc/mm slurry flow rate. The reduction in the step height of the silicon dioxide from the surface of the silicon wafer by CMP was measured using a stylus profilometer to determine the rate of step height reduction in terms of Angstroms of silicon dioxide per minute. The polishing rates are reported in Table III below.

TABLE III

| | | Silicon dioxide |
|---|---|---|
| Type of abrasive | Shape of structure | Step height reduction rate |
| Fixed abrasive pad | on pad | (A/mm) |
| SWR159 | Cylindrical | 500 |
| SWR192 | Pyramidal | 500 |

In summary, Example IV demonstrates that the step height reduction rates of the uniformly patterned 50% pattern density structures with just the pH adjusted DI water on a fixed abrasive polishing pad are very low.

### EXAMPLE V

A slurry was formed by dispersing 0.5 weight % ceria particles of average particle diameter 20 nm in deionized water. The pH of the slurry was adjusted to 10 by addition of a sufficient amount of 40% by weight solution of potassium hydroxide.

Blanket silicon wafers (6 inch diameter) having 3.5 micron silicon dioxide film layer applied by tetraethylorthosilicate (TEOS) precursor chemical vapor deposition were polished using a Westech 372 polisher and a fixed abrasive pad SWR159 with cylindrical structures on it. The polishing conditions were: the down pressure was varied as shown in Table IV; 0 psi back pressure; 40 rpm table speed; 40 rpm quill speed; 25 degrees C. temperature, and 300 cc/mm slurry flow rate. The amount of silicon dioxide removed from the surface of the silicon wafer by CMP was measured using an optical interferometer to determine the rate of removal in terms of Angstroms of silicon dioxide per minute.

Blanket silicon wafers (6 inch diameter) having 0.3 micron silicon nitride film layer applied by low pressure chemical vapor deposition were polished with the slurry described above and the same polishing equipment and conditions. The amount of silicon nitride removed from the surface of the silicon wafer by CMP was measured using an optical interferometer to determine the rate of removal in terms of Angstroms of silicon dioxide per minute. The polishing rate and silicon dioxide and silicon nitride selectivity is reported in Table IV below.

TABLE IV

| Applied | Silicon dioxide | Silicon nitride | |
|---|---|---|---|
| Down pressure | Removal rate | Removal rate | |
| (psi) | (A/min.) | (A/min.) | Selectivity |
| 3 | 2200 | 160 | ˜14 |
| 4 | 2600 | 160 | ˜17 |
| 6 | 3000 | 200 | ˜15 |

In summary, Example V illustrates that blanket silicon dioxide removal rates have dramatically increased with the supply of free abrasives on the fixed abrasive pad. A good silicon dioxide and silicon nitride selectivity greater than 10 was obtained even at high down pressures without addition of any chemical additives to suppress nitride removal rates.

### EXAMPLE VI

A slurry was formed by dispersing 0.5 weight % ceria particles of average particle diameter 20 nm in deionized water. The pH of the slurry was adjusted to 10 by addition of a sufficient amount of 40% by weight solution of potassium hydroxide.

Blanket silicon wafers (6 inch diameter) having 3.5 micron silicon dioxide film layer applied by tetraethylorthosilicate (TEOS) precursor chemical vapor deposition were polished using a Westech 372 polisher and a fixed abrasive pad SWR159 with cylindrical structures on it. The polishing conditions were: the down pressure was varied as shown in Table IV; 0 psi back pressure; 40 rpm table speed; 40 rpm quill speed; 25 degrees C. temperature, and the slurry flow rate was varied as shown in Table V. The amount of silicon dioxide removed from the surface of the silicon wafer by CMP was measured using an optical interferometer to determine the rate of removal in terms of Angstroms of silicon dioxide per minute. The polishing rates are reported in Table V below.

TABLE V

| Slurry | Silicon dioxide |
|---|---|
| Flow rate | Removal rate |
| (cc/mm) | (A/min) |
| 150 | 2000 |
| 300 | 2200 |

In summary, Example VI illustrates that the slurry flow rate is not a critical issue.

### EXAMPLE VII

A slurry was formed by dispersing 0.5 weight % or 3.0 weight % ceria particles of average particle diameter 20 nm, or 3.0 weight % silica particles of average particle diameter 200 nm in deionized water (shown in Table VI). The pH of the slurry was adjusted to 10 by addition of a sufficient amount of 40% by weight solution of potassium hydroxide.

Patterned silicon wafers (6 inch diameter) of an uniform pattern density of 50%, having a silicon dioxide film layer applied by tetraethylorthosilicate (TEOS) precursor chemical vapor deposition and the step height of the silicon dioxide ˜7300 Angstroms, were polished using a Westech 372 polisher and a fixed abrasive pad SWR159 with cylindrical structures on it, or a fixed abrasive pad SWR192 with pyramidal structures on it, or a fixed abrasive pad SWR176 with hexagonal structures on it (shown in Table V). Layers of different materials like silicon nitride may be present underneath the silicon dioxide film and above the silicon wafer in the ‘UP’ areas (active areas) in FIG. 1. The polishing conditions were: 3 psi down pressure; 0 psi back pressure; 40 rpm table speed; 40 rpm quill speed; 25 degrees C. temperature, and 300 cc/mm slurry flow rate. The reduction in the step height of the silicon dioxide from the surface of the silicon wafer by CMP was measured using a stylus profilometer to determine the rate of step height reduction in terms of Angstroms of silicon dioxide per minute. The step height reduction rates are reported in Table VI below.

TABLE VI

| | | Abrasive-slurry | Step hgt |
|---|---|---|---|
| Fixed abrasive | Structure shape | (abrasive conc- | redctn rate |
| Pad | fixed abrasive pad | wt %) | (A/min) |
| SWR159 | Cylindrical | silica (3 wt %) | ˜2000 |
| SWR159 | Cylindrical | ceria (0.5 wt %) | ˜6000 |
| SWR159 | Cylindrical | ceria (3 wt %) | ˜7000 |
| SWR192 | Pyramidal | ceria (3 wt %) | ˜8000 |
| SWR176 | Hexagonal | ceria (3 wt %) | ˜7000 |

In summary, Example VII illustrates that the step height reduction rate of uniform 50% pattern density structures has dramatically increased with the supply of free abrasives on the fixed abrasive pad.

It is to be understood that any amounts given herein are illustrative, and are not meant to be limiting. All ratios, parts, percentages, proportions, and other amounts stated herein are on a weight basis, unless otherwise stated herein, or otherwise obvious to one skilled in the art to which the invention pertains.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention. While preferred embodiments of the invention have been described using specific terms, this description is for illustrative purposes only. Variations and modifications can be effected within the spirit and scope of the invention as described hereinabove and as defined in the appended claims by a person of ordinary skill in the art, without departing from the scope of the invention. It is intended that the doctrine of equivalents be relied upon to determine the fair scope of these claims in connection with any other person's product which fall outside the literal wording of these claims, but which in reality do not materially depart from this invention.

### PARTS LIST

10 oxide-filled STI structure

11 pad-oxide layer

12 silicon wafer base

13 silicon nitride layer

14 trenches

15 silicon dioxide

16 “Down” areas

17 “Up” areas

18 oxide overfill

19 step

20 blanket wafer

21 fixed polishing pad

22 pad structures

23 nanoparticles

24 carrier

25 tubing

27 fixed pattern wafer

28 topographical structures

What is claimed is:

1. An aqueous composition for chemical mechanical planarization of a wafer or film using a fixed polishing pad, the composition comprising:
(a) from about 0.2 to about 10 weight % of abrasive nanoparticles having an average particle size of between about 10 and about 200 nanometers; and
(b) from about 90 to about 99.8 weight % of water;
wherein the pH of the composition is between about 3 and about 5 or between about 9 and about 12, and the composition does not comprise polyelectrolytes.

2. A composition according to claim 1 wherein the number of particles with a diameter greater than about 100 nanometers is less than about 1 weight %.

3. A composition according to claim 1 wherein the nanoparticles are ceria.

4. A composition according to claim 3 wherein the fixed polishing pad is a fixed abrasive pad.

5. A composition according to claim 4 wherein the pH of the composition is between about 9 and about 12.

6. A composition according to claim 5 wherein the amount of ceria nanoparticles is from about 0.2 to about 3 weight %.

7. A composition according to claim I wherein the nanoparticles are silica.

8. A composition according to claim 7 wherein the pH of the composition is between about 9 and about 11.

9. A composition according to claim 8 wherein the amount of silica nanoparticles is from about 1 to about 5 weight %.

10. A composition according to claim 1 wherein the nanoparticles are ceria and silica in a ratio of between about 10: 1 and about 1:10 ceria:silica.

11. A composition according to claim 2 further comprising from about 0.3 to about 3 weight % of a substantially water-soluble surfactant.

12. A composition according to claim 1 1 wherein the wafer is a fixed pattern wafer.

13. A composition according to claim 9 further comprising from about 0.3 to about 3 weight % of a substantially water-soluble anionic or nonionic surfactant.

14. A process according to claim 2 which does not comprise an amino acids additive.

15. A composition according to claim 2 wherein the particle size range of the nanoparticles is between about 10 and about 100 nanometers.

16. A composition according to claim 4 wherein the particle size range of the nanoparticles is between about 15 and about 50 nanometers.

17. A composition according to claim 16, which does not comprise any other ingredients.

18. A composition according to claim 1, wherein a substantial majority of the nanoparticles are silica nanoparticles coated with a plurality of smaller ceria nanoparticles, the average particle size of the ceria nanoparticles being less than about half the average particle size of the silica nanoparticles.

19. A composition according to claim 10, wherein the nanoparticles are silica nanoparticles having an average particle size of between about 10 and about 50 nanometers, a substantial number of the silica nanoparticles being substantially coated with ceria nanoparticles, the ceria nanoparticles having an average particle size between about 1 and about 5 nanometers.

20. A composition according to claim 1 wherein the nanoparticles are alumina.

21. A composition according to claim 20 wherein the film is a blanket film.

22. A composition according to claim 1 wherein the nanoparticles are polymers.

23. A composition according to claim 22 wherein the polishing pad is a fixed abrasive pad with cylindrical, pyramidal, hexagonal, square, or rectangular structures.

24. A composition according to claim 1 wherein the nanoparticles are zirconia.

25. A composition according to claim 2 wherein the nanoparticles are hematite.

26. A composition according to claim 1 wherein the nanoparticles are magnesia.

27. A composition according to claim 2 wherein the nanoparticles are titania or yttria.

28. A composition according to claim 15 wherein the nanoparticles are tin oxide.

29. An aqueous composition for chemical mechanical planarization of a shallow trench isolation film using a fixed abrasive pad, the composition comprising:
(a) from about 0.2 to about 10 weight % of abrasive nanoparticles having an average particle size of between about 10 and about 100 nanometers; and
(b) from about 90 to about 99.8 weight % of water;
wherein the pH of the composition is between about 9 and 12, and the composition does not comprise polyelectrolytes.

30. A one-step process for chemical mechanical planarization of a wafer, regardless of wafer topography, using a fixed polishing pad, the process comprising the steps of:
a) mechanically polishing the wafer with the pad; and
b) feeding an aqueous composition comprised of abrasive nanoparticles to the pad during planarization, the composition having a pH of between about 3 and about 5 or between about 9 and about 12.

31. A process according to claim 30 without an additional step of adding a polyelectrolyte solution to the pad.

32. A composition according to claim 30 wherein no other slurry is added to the pad during polishing.

33. A process according to claim 30 consisting essentially of steps a) and b).
